(19) United States
(12) Patent Application Publication
(10) Pub. No.: US 2023/0046307 A1
(43) Pub. Date: Feb. 16, 2023

(54) EPITAXIAL SUBSTRATE WITH 2D MATERIAL INTERPOSER, MANUFACTURING METHOD, AND MANUFACTURING ASSEMBLY

(71) Applicant: Hsiao Lei WANG, Taoyuan City (CN)

(72) Inventor: Hsiao Lei WANG, Taoyuan City (CN)

(21) Appl. No.: 17/790,850

(22) PCT Filed: Dec. 17, 2020
(86) PCT No.: PCT/CN2020/137030

§ 371 Date: Jul. 5, 2022

(30) Foreign Application Priority Data
Jan. 3, 2020 (CN) 202010006008.4

(51) Int. Cl. H01S 5/02; H01S 5/30; H01S 5/343

(52) U.S. Cl. CPC H01S 5/0206; H01S 5/3013; H01S 5/34333; H01S 5/0205

(57) ABSTRACT

Disclosed is an epitaxial substrate with a 2D material interposer on a surface of a polycrystalline substrate. The ultra-thin 2D material interposer is grown by van der Waals epitaxy. The lattice constant of a surface layer of the ultra-thin 2D material interposer and the coefficient of thermal expansion of the substrate base are highly fit with those of AlGaN or GaN. The ultra-thin 2D material interposer is of a single-layer structure or a composite-layer structure. An AlGaN or GaN single crystalline epitaxial layer is grown on the ultra-thin 2D material interposer by virtue of the van der Waals epitaxy. Therefore, the large-size substrate may be manufactured with far lower costs than related single crystal wafers.

### RELATED APPLICATIONS

This application is a national phase entry of International Application No. PCT/CN2020/137030, filed on Dec. 17, 2020, which claims priority to Chinese Application No. CN 202010006008.4, filed in China on Jan. 3, 2020. The entire contents of International Application No. PCT/CN2020/137030 and Chinese Application No. CN 202010006008.4 are hereby incorporated by reference.

### TECHNICAL FIELD

The present disclosure relates to an epitaxial substrate with a 2D material interposer as well as a manufacturing method and manufacturing assembly thereof, the epitaxial substrate with the 2D material interposer being applicable to AlGaN-based wide bandgap components and GaN-based laser diodes.

### BACKGROUND

In the manufacturing process of light-emitting diode or laser diode (LD) components, epitaxy has an important influence on the quality of products. The influence on quality even includes the luminous efficiency, durability and the like. The reason is that light-emitting diodes particularly require electrons and holes to cooperate with each other during crystal excitation to generate photons smoothly. In contrast, if defects occur in a material structure, the possibility of being hindered by the defects during the mutual combination of electrons and holes will be increased, resulting in the deterioration of luminous effect. Gallium nitride (GaN) is selected as a main luminous material of light-emitting diodes, it is usually grown on a substrate by epitaxy, and a crystalline structure of produced gallium nitride is largely affected by the used substrate. In order to improve the luminous efficiency, durability and other characteristics related to the quality of the light-emitting diodes, several conditions are usually taken into account in this technical field when a suitable substrate material is selected. Generally, the substrate material is expected to be a single crystalline material minimized in defect density, and only when the substrate material is fit with an epitaxial material in terms of crystalline structure, lattice constant and coefficient of thermal expansion (CTE), the crystal quality of light-emitting diodes can be prevented from being affected as much as possible during the epitaxy.

According to the current technology, single crystalline sapphire (Sapphire) is most commonly used as a substrate material, mainly due to its advantages of good chemical stability, mature manufacturing technology and the like; and due to an increase in production capacity in recent years, sapphire substrates, compared with other alternatives such as nitrogen aluminum (AlN) or even gallium nitride (GaN) substrates and the like, better meet economic requirements. However, due to imperfect fit between sapphire and epitaxial materials in terms of crystalline structure, lattice constant and coefficient of thermal expansion (CTE), the high defect density of GaN or AlGaN epitaxial layers affects the application of laser diodes (LDs) and the performance improvement of ultraviolet light-emitting diodes (UV LEDs). The luminous wavelength of the UVC LEDs in the deep ultraviolet range has the most disinfection and sterilization effect. Current mercury lamps which are inefficient, energy-consuming and harmful to the environment will be effectively replaced, and there is a bottleneck in a mass production technology for aluminum nitride substrates, which has great potential for development in people's livelihood and daily disinfection and sterilization applications, but is currently most suitable for UV LEDs. The development of UVC LEDs is still mainly focused on poorly fitted sapphire substrates, resulting in great obstacles to performance improvement.

The melting points of both aluminum nitride and gallium nitride are above 2500° C. and there is a problem of high vapor pressure. In other words, if it is desired to directly manufacture single crystalline substrates of the above two materials by melting-based crystal growth, the manufacturing cost will be higher, and relatively more waste heat will be generated, causing inevitable pollution to the environment. For crystal growth by vapor phase methods, at present, single crystalline gallium nitride substrates are produced by adopting hydride vapor phase epitaxy (HYPE) in gallium nitride crystal growth, and due to the limitation of production costs and yield conditions, 4-inch substrates are massively produced with extremely high costs. In fact, the defect density in the above vapor phase method is still higher than that in other liquid phase crystal growth procedures, but due to low crystal growth rate in other procedures and higher cost of mass production, the commercial mainstream is still limited to HYPE under the consideration of market demand, component performance and trade-off between substrate cost and supply. Literatures point out that the GaN crystal growth rate in the vapor phase method is still possible to be increased by several times and good crystallinity is maintained, but due to the deterioration of defect density, the cost of GaN substrates is not reduced currently. As for an aluminum nitride crystal growth technology, single crystalline aluminum nitride substrates are produced by adopting physical vapor transport (PVT) as one of vapor phase methods. Due to the limitation of production technologies and yields, only two manufacturers in the world have capacity of mass production. At present, only 2-inch substrates are massively produced with extremely high costs by a few manufacturers, so they cannot be widely supplied to the market. Because of the chemical characteristics of aluminum nitride and the limitation of hardware components in physical vapor transport, inevitable carbon (C) and oxygen (O) impurities exist in a finished single crystalline product, and also affect the component characteristics to a certain extent.

TABLE 1

| | | | | Coefficient of |
|---|---|---|---|---|
| | Crystalline | Lattice constant | | thermal expansion |
| Material | structure | a | c | ×10⁻⁶ × K⁻¹ |
| Gallium nitride | Wurtzite | 0.31885 | 0.5185 | αₐ 5.59 |
| (GaN) | | | | α_{c} 3.17 |
| Aluminum nitride | Wurtzite | 0.31106 | 0.49795 | αₐ 4.15 |
| (AlN) | | | | α_{c} 5.27 |
| Zinc oxide (ZnO) | Wurtzite | 0.32496 | 0.52065 | αₐ 4.31 |
| | | | | α_{c} 2.49 |
| Silicon carbide | Wurtzite | 0.30806 | 1.51173 | αₐ 4.3 |
| (SiC) 6H | | | | α_{c} 4.7 |
| Sapphire | Rhombohedral | 0.4765 | 1.2982 | αₐ 6.66 |
| | | | | α_{c} 5 |
| Silicon (Si) | Diamond | 0.5431 | | 2.6 |

In terms of crystalline structure, thermal properties and lattice constant, a zinc oxide (ZnO) single crystalline material is a relatively suitable substrate material in former terms, so it has attracted technology developers to engage in research. However, zinc oxide is not widely used in the technical field today, mainly due to that zinc oxide has high chemical activity and is easily corroded by hydrogen-containing substances in subsequent epitaxial processes, resulting in poor quality of an epitaxial layer. As shown in FIG. 1, during the epitaxy, a zinc oxide substrate will be etched by hydrogen and zinc is rapidly diffused into the epitaxy layer, resulting in poor epitaxy quality. By adjusting the manufacturing process to improve the epitaxy quality, zinc and oxygen are still diffused and doped into crystalline grains of light-emitting diodes, causing unsatisfactory luminous characteristics, and making this structure unable to meet the actual market demand.

The same situation may also exist in other optoelectronic component substrate-epitaxy combinations currently in use, such as silicon carbide (SiC) or gallium arsenide (GaAs). A single crystalline silicon carbide substrate is currently a substrate material for high-performance power semiconductors and high-end light-emitting diodes. A single crystal growth procedure is physical vapor transport (PVT) in vapor phase methods. A high-quality and large-size silicon carbide single crystal growth technology is highly difficult, and a high-end mass production technology is in the hands of a few manufacturers, so there is still a lot of room for improvement in affected application cost.

Two-dimensional (2D) materials belong to a rapidly developing emerging field. Graphene is the most well-known material that has first attracted a lot of research and development investment in the 2D material family Its two-dimensional layered structure has special or excellent physical/chemical/mechanical/optoelectronic properties. There is no strong bonds between layers, which are bonded only by van der Waals force, and it also indicates that there are no dangling bonds on the surface of the layered structure. At present, graphene has been confirmed to have extensive and excellent application potential. Graphene research and development work is widely carried out around the world, and also drives the research and development of more 2D materials, including hexagonal boron nitride (hBN), transition metal dichalcogenides (TMDs) and black phosphorus of which more research and development achievements also have been accumulated in the 2D material family. As shown in FIG. 2 and FIG. 3, the above materials each have specific material properties and application potential. The development of manufacturing technologies for related materials is also being actively advanced. In addition to excellent optoelectronic properties, graphene, hBN and MoS₂ as one of TMDs materials are considered to have excellent diffusion barrier properties and varying degrees of high temperature stability, especially hBN has excellent chemical inertness and high-temperature oxidation resistance.

Due to the performance of the above layered structure and the characteristic of bonding between layers by van der Waals force, the technical feasibility of making two or more materials in the 2D material family into layered stacked hetero-structures is greatly increased. In addition to combining different properties, the hetero-structures make it possible to create new application properties or make new components. At present, the research and development in the fields of optoelectronics and semiconductors are quite active. FIGS. 4A and 4B are schematic diagrams of mechanically formed stacks, and FIGS. 5A and 5B are schematic diagrams of physical or chemical vapor deposition.

The van der Waals force bonding characteristic of 2D materials is also applied to epitaxial substrates made of traditional 3D materials. Its focus is that in an epitaxial technology, an epitaxial material must be very well fit with a substrate material in terms of crystalline structure, lattice constant and coefficient of thermal expansion (CTE), but in reality, it is often encountered that suitable substrate materials lack in the present disclosure, or ideal substrate materials are expensive or difficult to obtain. At this time, 2D materials provide another solution for heteroepitaxial substrates, which is the so-called van der Waals Epitaxy. A mechanism that van der Waals Epitaxy may be beneficial to heteroepitaxy comes from replacement of direct chemical bonds of a traditional epitaxial interface with van der Waals force bonding, which will relieve stress or strain of misfitted lattice and thermal expansion in an epitaxial procedure to a certain extent, so that the quality of an epitaxial layer is improved, or the introduction of 2D materials and van der Waals Epitaxy can make it possible for some heteroepitaxial technologies which cannot be practically applied before. Relevant studies also pointed out that when the above 2D materials have mutually stacked hetero-structures, interactive force is mainly van der Waals force; while epitaxy of 3D materials is performed on 2D materials, due to the existence of dangling bonds of the 3D materials on an interface and the contribution to bonding force of the interface, this epitaxy is not essentially pure van der Waals Epitaxy or more precisely Quasi van der Waals Epitaxy; and in either case, the fit between lattice and thermal expansion undoubtedly still plays a certain role in final epitaxy quality, and both a 2D material interposer and a substrate material contribute to the overall fit. The above layered 2D materials have hexagon or honeycomb structures, and are considered to be structurally compatible with materials having Wurtzite and Zinc-Blende structures during epitaxy. Main epitaxial materials in related fields of the present disclosure all belong to this type of structures.

Based on the use of epitaxial substrates, single crystal is one of the requirements for ensuring the epitaxy quality. The growth of general 2D materials tends to correlate with the crystal orientation of a crystalline substrate during the nucleation stage. When the substrate is made of a general metal foil, due to a polycrystalline structure, the 2D materials are already formed in different directions during the nucleation stage, and after crystalline nuclei are polymerized into a continuous film along with growth, domains with different orientations are still present instead of single crystals; and when the substrate is made of a single crystalline material such as sapphire, the specific nucleation orientation possibly occurring due to the symmetrical correlation of two structures is not unique, and a single crystalline continuous film cannot be formed. In recent researches, it has found that when a copper foil is heat-treated to form a copper foil with a specific lattice orientation by improving an existing process, anisotropic lattice domain features formed during the growth of graphene and hexagonal boron nitride (hBN) as 2D materials can be eliminated to grow a single crystalline graphene and hexagonal boron nitride continuous film.

In recent years, many studies have indicated that the 2D material family is generally ideal substrate materials for heteroepitaxy, such as epitaxial substrates made of hBN considered as superexcellent transition metal dichalcogenides (TMDs) materials, and a single crystalline continuous film made of MoS₂, WS₂, MoSe₂, WSe₂ and other TMD materials and maintaining the surface area up to 95% can be epitaxially grown on the surface of single crystalline hBN.

In recent years, studies have pointed out that layered MoS₂, WS₂, MoSe₂, WSe₂ and other TMD materials with good crystallinity can be grown on the c-plane sapphire surface of single crystal by CVD and other methods. The grown TMD material can contain two crystal orientations (0° and 60°) (with reference to literatures: Nature 2019, v. 567, 169-170). For AlGaN and GaN materials concerned by the present disclosure, a crystalline structure has hexagonal symmetry (as shown in FIG. 6) on an epitaxial junction. The above TMD layer does not constitute a single crystalline layer, but in theory, it does not prevent AlGaN and GaN epitaxial layers from forming single crystals when used as an epitaxial substrate. At present, a technology for peeling off the TMD layer from the surface of sapphire and transferring it to the surfaces of other substrates has been practically applied in a large area, and a sapphire substrate can be recycled, so the technology is already a feasible manufacturing process for commercial mass production (with reference to literatures: ACS Nano 2015, 9, 6, 6178-6187). Therefore, in addition to the previous method for manufacturing the TMD single crystalline continuous film, the transfer of the TMD layer on the surface of sapphire to the substrate highly fit with the AlGaN and GaN in coefficient of thermal expansion is another applicable feasible solution for mass production.

An existing process, as shown in FIG. 7, involves performing intrinsic or hetero epitaxy on the surface of a high-quality single crystalline substrate. At present, AlGaN-based wide bandgap components are epitaxial on sapphire or aluminum nitride (AlN), and GaN-based laser diodes are epitaxial on high-quality single crystalline GaN. AlGaN-based wide bandgap components are epitaxial on sapphire. Due to poor fit, the defect density is high (defect density of an epitaxial layer is more than 10⁸/cm²), seriously affecting the efficiency of components. UVC LED components are internally reflected due to large difference in refractive index between AlGaN and sapphire, thus reducing the overall luminous efficiency. At present, the external quantum efficiency (EQE) of components on the market is far lower than 10%. High-quality AlN single crystalline substrates are ideal substrates for AlGaN epitaxy. Because the lattice and the coefficient of thermal expansion are highly fit with those of an epitaxial layer, the defect density of the epitaxial layer is less than 10⁵/cm². Due to the fact that a PVT manufacturing technology contains specific impurities which just absorb UVC band spectrum, the external quantum efficiency (EQE) of components on the market is far lower than 10%. Despite this, a PVT AlN manufacturing technology can only produce 2-inch wafers with low output and high cost, and the production capacity of only two PVT AlN suppliers in the world is also controlled by a specific group, so it is difficult to meet the market supply demand High-quality single crystalline GaN for epitaxy of GaN-based laser diodes has high manufacturing cost, and due to the limitation of the manufacturing technology, the defect density of HVPE GaN crystals is 100-1000 times that of sapphire substrates and reaches a level of 10⁵/cm², and only 4-inch wafers are mainly massively produced. Because the efficiency of laser diodes is highly sensitive to the defect density of the epitaxial layer, existing GaN single crystal wafers are not ideal choices, but there are no better solutions on the market.

### SUMMARY

An objective of the present disclosure is to provide an epitaxial substrate with a 2D material interposer.

The present disclosure further provides a manufacturing method of the above epitaxial substrate.

The present disclosure further provides a manufacturing assembly of the above epitaxial substrate, an AlGaN-based wide bandgap component and a GaN-based laser diode.

In order to achieve the above objective, the present disclosure adopts the following solution:

An epitaxial substrate with a 2D material interposer on a surface of a polycrystalline substrate, wherein the ultra-thin 2D material interposer is grown by van der Waals epitaxy; the lattice constant of a surface layer of the ultra-thin 2D material interposer and the coefficient of thermal expansion of the polycrystalline substrate base are highly fit with those of AlGaN or GaN respectively; the ultra-thin 2D material interposer is of a single-layer structure or a composite-layer structure; and an AlGaN or GaN single crystalline epitaxial layer is grown on the ultra-thin 2D material interposer by the van der Waals epitaxy.

The thickness of the ultra-thin 2D material interposer ranges from 0.5 nm to 1000 nm.

The ultra-thin 2D material interposer is a 2D layer applicable to AlGaN or GaN epitaxy.

The ultra-thin 2D material interposer is of a composite-layer structure formed by a top layer and a bottom layer, the top layer is a 2D layer applicable to AlGaN or GaN epitaxy, and the bottom layer is a 2D material suitable as a single crystalline base layer.

The lattice constant misfit is not more than 5% between the lattice constant of AlN or GaN and the lattice constant (a) of a single-layer structure or the top layer of a composite-layer structure of the ultra-thin 2D material interposer applicable to AlGaN or GaN epitaxy.

The differences between the coefficients of thermal expansion of the polycrystalline substrate base and AlN or GaN in the direction parallel to the van der Waals epitaxy interface is not more than 1.5×10⁻⁶° C.⁻¹. The stable material quality may be maintained in AlGaN and GaN epitaxial procedures without adverse effects or damage.

A manufacturing method of the epitaxial substrate with the 2D material interposer includes the following steps:

step 1: pretreat a polished polycrystalline substrate to comply with a starting material ready for an epitaxial growth in subsequent manufacturing procedures;

step 2: grow a single crystalline 2D material layer by existing manufacturing processes and cover the surface of a polycrystalline substrate with the 2D material layer of a single-layer structure or a van der Waals epitaxially grown composite-layer structure with a heterojunction to serve as an interposer; alternatively, transfer a non-single crystalline 2D material layer applicable to AlGaN and GaN epitaxy to the surface of the polycrystalline substrate material by existing procedures to serve as an interposer, and form the substrate, wherein the lattice constant of a surface layer and the coefficient of thermal expansion of the substrate base are highly fit with those of AlGaN or GaN respectively; and

step 3: grow an AlGaN or GaN single crystalline epitaxial layer on the interposer by utilizing the van der Waals epitaxy to finish the epitaxial substrate with the 2D material interposer.

In the step 2, the processes involved in the 2D material interposer include but not limited to the thin film growth, deposition, mechanical transfer, and coating; and the total thickness of the 2D material interposer of a single-layer structure or a composite-layer structure is in the range of 0.5 nm to 1000 nm.

In the step 2, the ultra-thin single crystalline 2D material interposer is manufactured by the following steps starting with a metal foil as the initial substrate: step A: make polycrystalline metal foils slowly pass through a hot zone at a temperature slightly lower than the nominal melting point of copper in an established procedure in order to form single crystalline metal foils; and select the single crystalline metal foils with the preferred crystal orientation suitable for later 2D material growth; step B: cut one selected metal foil in step A to form a foil with a sharp tip at one end in the preferred crystal orientation; step C: physically joint the sharp-tipped foil in step B with an untreated polycrystalline metal foil; step D: repeat the thermal treatment of step A on the jointed metal foil from step C to form a single crystalline metal foil with the preferred crystal orientation; step E: epitaxially grow a thin single crystalline 2D material interposer on top of the metal foil from step D; step F: transfer the grown single crystalline 2D material interposer from the surface of the metal foil in step E to the surface of the pretreated polycrystalline substrate by established procedures, supplemented by necessary clamping fixtures to align the lattice orientation to the substrate flat or the substrate notch; and step G: epitaxially grow other types of thin single crystalline 2D materials as needed to meet the lattice fitting requirements of subsequent epitaxial procedures.

In the step 3, subsequent epitaxial and other necessary manufacturing procedures may be continued on the epitaxial substrate with the 2D material interposer, that is to say, components including wide bandgap optoelectronic and electronic components and GaN-based laser diodes are manufactured, and an AlGaN-based wide bandgap component or a GaN-based laser diode component may be formed.

With the adoption of the above solution, the present disclosure provides a brand new substrate. The lattice constant of 2D materials (WS₂ and MoS₂) is highly fit with that of c-plane AlGaN and GaN, and the thermal expansion properties of polycrystalline sintered substrates (such as sintered AlN) are highly fit with that of AlGaN and GaN. As a result, a feasible technology is provided for epitaxy of single crystalline layers on polycrystalline substrates, and a sintered (AlN) technology is combined to manufacture large-size (6 inches and above) substrates with far lower cost than related single crystal wafers (GaN, AlN and sapphire). The present disclosure simultaneously solves the problems of epitaxial substrates of existing UVC LEDs and GaN-based laser diodes and is capable of significantly reducing procedure costs, effectively improving the efficiency of the AlGaN-based wide bandgap optoelectronic and electronic components and the GaN-based laser diode components and reducing manufacturing costs.

### BRIEF DESCRIPTION OF DRAWINGS

FIG. 1 is a schematic diagram of a zinc oxide substrate corroded during the epitaxy;

FIG. 2 is a schematic structural diagram of a two-dimensional material transition metal dichalcogenides (TMDs);

FIG. 3 is a schematic structural diagram of a two-dimensional material hexagonal boron nitride (hBN);

FIGS. 4A and 4B are schematic diagrams of mechanically formed stacks;

FIGS. 5A and 5B are schematic diagrams of physical and chemical vapor deposition;

FIG. 6 is a hexagonal symmetry structure diagram of a crystalline structure on an epitaxial junction;

FIG. 7 is a schematic diagram of intrinsic or hetero epitaxy on a surface of an existing high-quality single crystalline substrate;

FIG. 8 is a schematic structural diagram of a first embodiment of the present disclosure;

FIG. 9 is a schematic structural diagram of a second embodiment of the present disclosure; and

FIG. 10 is a flowchart of a manufacturing method of the present disclosure.

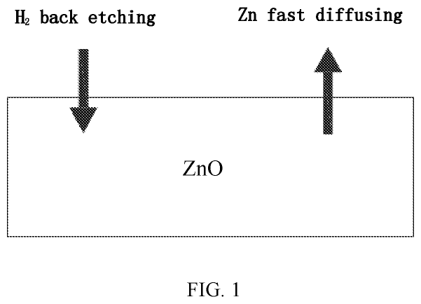

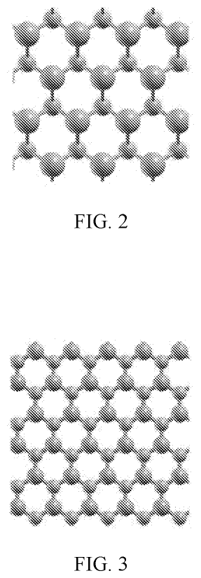

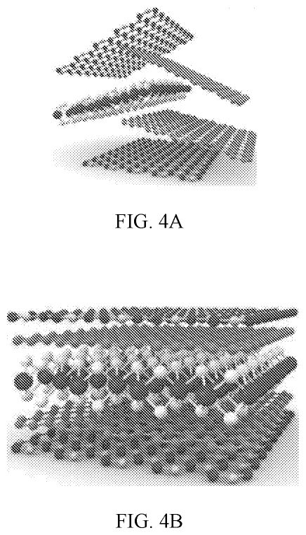

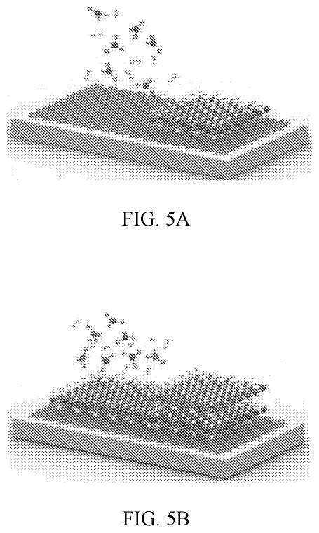

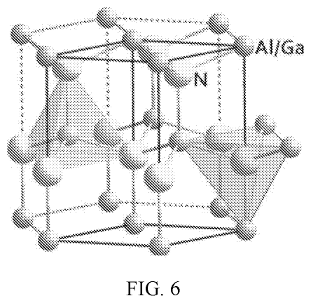

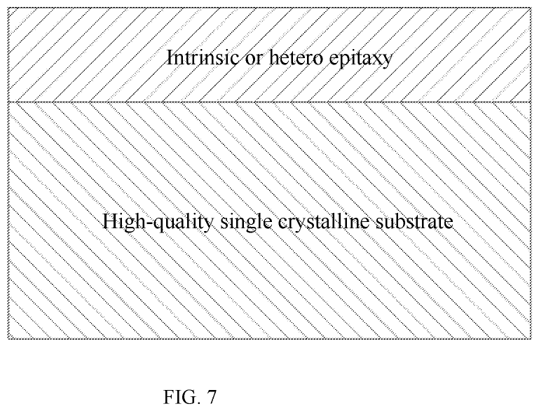

### DESCRIPTION OF EMBODIMENTS

The present disclosure is further described below with reference to the accompanying drawings and specific embodiments.

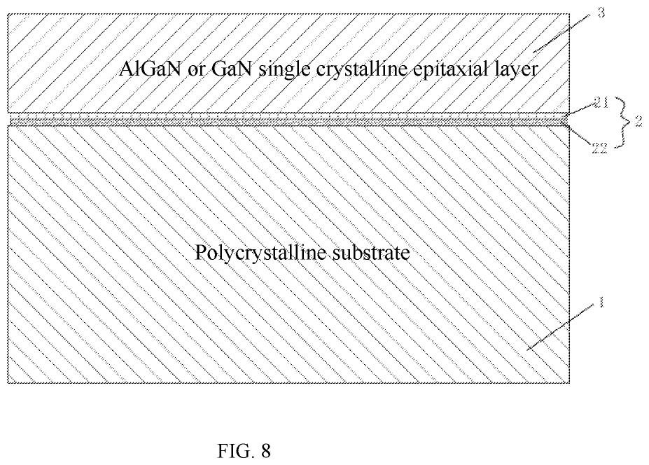

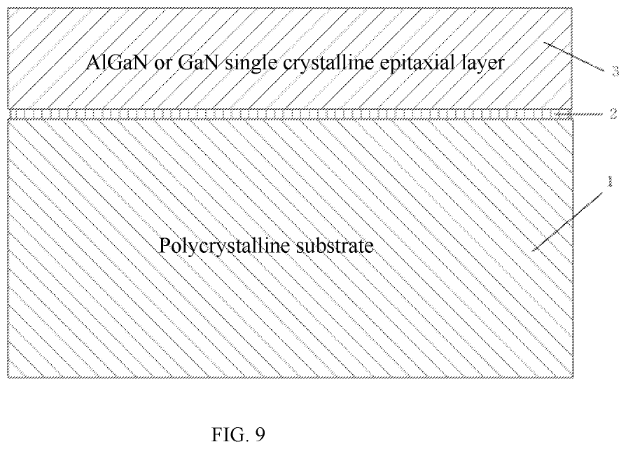

Referring to FIG. 8 and FIG. 9, the present disclosure provides an epitaxial substrate with a 2D material interposer on a surface of a polycrystalline substrate 1, wherein the ultra-thin 2D material interposer 2 is grown by van der Waals epitaxy; the lattice constant of a surface layer of the ultra-thin 2D material interposer 2 and the coefficient of thermal expansion of the substrate base are highly fit with those of AlGaN or GaN; the ultra-thin 2D material interposer 2 is of a single-layer structure (as shown in FIG. 9) or a composite-layer structure (heterogeneous material bonding, as shown in FIG. 8); and an AlGaN or GaN single crystalline epitaxial layer 3 is grown on the ultra-thin 2D material interposer 2 by virtue of the van der Waals epitaxy.

The polycrystalline substrate 1 adopts sintered AlN, other ceramic or metal substrates.

The thickness of the ultra-thin 2D material interposer 2 ranges from 0.5 nm to 1000 nm.

The ultra-thin 2D material interposer 2 is a 2D layer applicable to AlGaN or GaN epitaxy, such as a WS₂ or MoS₂ single-layer structure, as shown in FIG. 9.

The ultra-thin 2D material interposer 2 is of a composite-layer structure formed by a top layer 21 and a bottom layer 22, the top layer 21 is a 2D layer applicable to AlGaN or GaN epitaxy, such as WS₂ or MoS₂, and the bottom layer 22 is a 2D material suitable as a single crystalline base layer, such as hexagonal boron nitride (hBN). The lattice constant misfit is not more than 5% between the lattice constant of AlN or GaN and the lattice constant (a) of a single-layer structure or the top layer 21 of a composite-layer structure of the ultra-thin 2D material interposer 2 applicable to AlGaN or GaN epitaxy, such as WS₂, MoS₂ or other 2D materials.

The differences between the coefficients of thermal expansion (CTE) of the polycrystalline substrate base and AlN or GaN in the direction parallel to the van der Waals epitaxy interface is not more than 1.5×10⁻⁶° C.⁻¹. The stable material quality may be maintained in AlGaN and GaN epitaxial procedures without adverse effects or damage.

TABLE 2

| Material | Lattice constant a (nm) |
|---|---|
| Hexagonal boron nitride (hBN) | 0.25 |
| Graphene | 0.246 |
| WS₂ | 0318 |
| MoS₂ | 0.3161 |
| WSe₂ | 0.3297 |
| MoSe₂ | 0.3283 |

According to the single crystalline 2D material interposer with a heterojunction in the present disclosure, a single crystalline hBN layer is manufactured by existing processes and is transferred to the surface of the polycrystalline substrate 1 by the existing processes, and then a 2D material of the top layer is completed on the surface layer. The adopted hBN is an embodiment, which is not limited to the hBN.

The present disclosure further provides a new method. A lattice orientation of the single crystalline 2D material interposer is dependent on a wafer flat or wafer notch of an original substrate to ensure that the manufactured single crystalline substrate and a traditional substrate keep the consistency of lattice orientation or customization requirements of customers.

The present disclosure provides a manufacturing method of the epitaxial substrate with the 2D material interposer, including the following steps:

step 1: a polished polycrystalline substrate 1 (wafer) is pretreated to comply with an epitaxial growth grade and is subjected to appropriate pretreatment (including wafer cleaning) as a starting material ready for an epitaxial growth in subsequent manufacturing procedures;

step 2: a single crystalline 2D material layer is grown by existing manufacturing processes, and the surface of a polycrystalline substrate material is covered with the 2D material layer of a single-layer structure or a van der Waals epitaxially grown composite-layer structure with a heterojunction to serve as an interposer 2; alternatively, a non-single crystalline 2D material layer applicable to AlGaN and GaN epitaxy is grown on the surface of sapphire and then is peeled off and transferred to the surface of the polycrystalline substrate material by existing procedures to serve as an interposer 2, and the substrate is formed, wherein the lattice constant of a surface layer and the coefficient of thermal expansion of the substrate base are highly fit with those of AlGaN and GaN respectively; and

step 3: an AlGaN or GaN single crystalline epitaxial layer 3 is grown on the interposer 2 by utilizing the van der Waals epitaxy to finish the epitaxial substrate with the 2D material interposer.

In the step 2, the processes involved in the 2D material interposer include but not limited to the thin film growth, deposition, mechanical transfer, and coating; and the total thickness of the 2D material interposer of a single-layer structure or a composite-layer structure is in the range of 0.5 nm to 1000 nm.

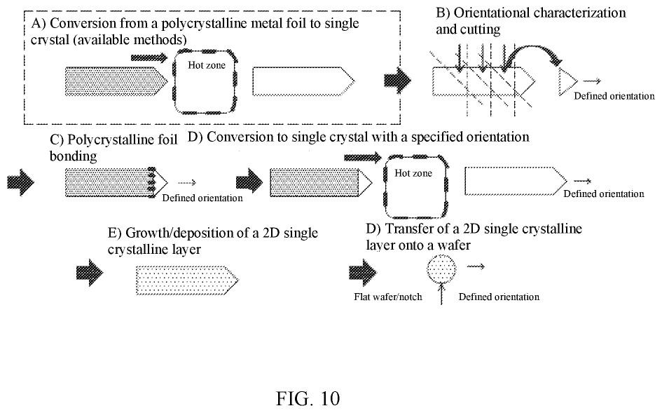

As shown in FIG. 10, in the step 2, the ultra-thin single crystalline 2D material interposer is manufactured by the following steps starting with a metal foil as the initial substrate: step A: polycrystalline copper foils are enabled to slowly pass through a hot zone at a temperature slightly lower than the nominal melting point of copper in an established procedure in order to form single crystalline metal foils; and the single crystalline copper foils (such as Cu(110) applicable to the growth of single crystalline hBN) with the preferred crystal orientation suitable for later 2D material growth are selected; step B: orientational characterization and cutting: one selected metal foil in step A is cut to form a foil with a sharp tip at one end in the preferred (specific) crystal orientation; step C: the sharp-tipped foil in step B is physically jointed with an untreated polycrystalline metal foil; step D: the thermal treatment of step A is repeated on the jointed metal foil from step C to form a single crystalline metal foil with the preferred crystal orientation; step E: a thin single crystalline 2D material interposer (such as Cu(110) applicable to the growth of single crystalline hBN) is epitaxially grown/deposited on top of the metal foil from step D; step F: the thin single crystalline 2D material interposer is transferred from the surface of the metal foil in step E to the surface of the pretreated polycrystalline substrate by established procedures, supplemented by necessary clamping fixtures to align the lattice orientation to the substrate flat or the substrate notch; and step G: other types of thin single crystalline 2D materials are epitaxially grown as needed to meet the lattice fitting requirements of subsequent epitaxial procedures.

Further, subsequent epitaxial and other necessary manufacturing procedures may be continued on the epitaxial substrate with the 2D material interposer, for example, components including wide bandgap optoelectronic and electronic components such as AlGaN UVC LEDs (but not limited to UVC LEDs) and GaN-based laser diodes are manufactured, and an AlGaN-based wide bandgap component or a GaN-based laser diode component (AlGaN is used for C-band LEDs in UVC LEDs; and GaN is used for blue laser diodes) may be formed.

The present disclosure solves the problems of epitaxial substrates of existing UVC LEDs and GaN-based laser diodes and is capable of significantly reducing procedure costs, effectively improving the efficiency of the AlGaN-based wide bandgap optoelectronic and electronic components and the GaN-based laser diode components and reducing manufacturing costs.

The above are only preferred embodiments of the present disclosure, and are not intended to limit the present disclosure. It should be pointed out that after this description is read, the equivalent changes made by those skilled in the art according to the design idea of the present disclosure all fall into the scope of protection of the present disclosure.

1. An epitaxial substrate with a two-dimensional (2D) material interposer on a surface of a polycrystalline substrate, wherein the ultra-thin 2D material interposer is grown by van der Waals epitaxy; a lattice constant of a surface layer of the ultra-thin 2D material interposer and a coefficient of thermal expansion of the polycrystalline substrate base are highly fit with those of AlGaN or GaN respectively; the ultra-thin 2D material interposer is of a single-layer structure or a composite-layer structure; and an AlGaN or GaN single crystalline epitaxial layer is grown on the ultra-thin 2D material interposer by the van der Waals epitaxy.

2. The epitaxial substrate with a 2D material interposer according to claim 1, wherein a thickness of the ultra-thin 2D material interposer ranges from 0.5 nm to 1000 nm.

3. The epitaxial substrate with a 2D material interposer according to claim 1, wherein the ultra-thin 2D material interposer is a 2D layer applicable to AlGaN or GaN epitaxy.

4. The epitaxial substrate with a 2D material interposer according to claim 1, wherein the ultra-thin 2D material interposer is a composite-layer structure formed by a top layer and a bottom layer, the top layer is a 2D layer applicable to AlGaN or GaN epitaxy, and the bottom layer is a 2D material suitable as a single crystalline base layer.

5. The epitaxial substrate with a 2D material interposer according to claim 1, wherein a lattice constant misfit is not more than 5% between a lattice constant of AlN or GaN and a lattice constant of a single-layer structure or a top layer of a composite-layer structure of the ultra-thin 2D material interposer applicable to AlGaN or GaN epitaxy.

6. The epitaxial substrate with a 2D material interposer according to claim 1, wherein differences between the coefficient of thermal expansion of the polycrystalline substrate base and coefficients of thermal expansion of AlN or GaN in a direction parallel to a van der Waals epitaxy interface is not more than 1.5×10⁻⁶° C.⁻¹.

7. The epitaxial substrate with a 2D material interposer according to claim 1, wherein a manufacturing method comprises the following steps:
step 1: pretreat a polished polycrystalline substrate to comply with a starting material ready for an epitaxial growth in subsequent manufacturing procedures;
step 2: grow a single crystalline 2D material layer by existing manufacturing processes and cover a surface of the polished polycrystalline substrate with the single crystalline 2D material layer of a single-layer structure or a van der Waals epitaxially grown composite-layer structure with a heterojunction to serve as an interposer; alternatively, transfer a non-single crystalline 2D material layer applicable to AlGaN and GaN epitaxy to the surface of the the polished polycrystalline substrate material by existing procedures to serve as the interposer, and form the epitaxial substrate, wherein the lattice constant of the surface layer and the coefficient of thermal expansion of the epitaxial substrate are highly fit with those of AlGaN or GaN respectively; and
step 3: grow the AlGaN or GaN single crystalline epitaxial layer on the interposer by utilizing the van der Waals epitaxy to finish the epitaxial substrate with the 2D material interposer.

8. The epitaxial substrate with a 2D material interposer according to claim 7, wherein in the step 2, the processes involved in the 2D material interposer include thin film growth, deposition, mechanical transfer, and coating; and a total thickness of the 2D material interposer of the single-layer structure or the composite-layer structure is in a range of 0.5 nm to 1000 nm.

9. The epitaxial substrate with a 2D material interposer according to claim 7, wherein in the step 2, the ultra-thin single crystalline 2D material interposer is manufactured by the following steps starting with a metal foil as an initial substrate. step A: make polycrystalline metal foils slowly pass through a hot zone at a temperature slightly lower than a nominal melting point of copper in an established procedure in order to form single crystalline metal foils; and select the single crystalline metal foils with a crystal orientation suitable for later 2D material growth;
step B: cut one selected metal foil in step A to form a foil with a sharp tip at one end in the crystal orientation;
step C: physically joint the sharp-tipped foil in step B with an untreated polycrystalline metal foil;
step D: repeat the thermal treatment of step A on the jointed metal foil from step C to form a single crystalline metal foil with the crystal orientation;
step E: epitaxially grow a thin single crystalline 2D material interposer on top of the metal foil from step D; and
step F: transfer the grown single crystalline 2D material interposer from a surface of the metal foil in step E to the surface of the pretreated polycrystalline substrate by established procedures, supplemented by necessary clamping fixtures to align a lattice orientation to a substrate flat or a substrate notch.

10. Apply the epitaxial substrate with a 2D material interposer made by claim 1 for a subsequent epitaxial device growth toward manufacture of AlGaN-based wide bandgap components or the GaN-based laser diode components.

11. Apply the epitaxial substrate with a 2D material interposer made by claim 2 for a subsequent epitaxial device growth toward manufacture of AlGaN-based wide bandgap components or the GaN-based laser diode components.

12. Apply the epitaxial substrate with a 2D material interposer made by claim 3 for a subsequent epitaxial device growth toward manufacture of AlGaN-based wide bandgap components or the GaN-based laser diode components.

13. Apply the epitaxial substrate with a 2D material interposer made by claim 4 for a subsequent epitaxial device growth toward a manufacture of AlGaN-based wide bandgap components or the GaN-based laser diode components.

14. Apply the epitaxial substrate with a 2D material interposer made by claim 5 for a subsequent epitaxial device growth toward a manufacture of AlGaN-based wide bandgap components or the GaN-based laser diode components.

15. Apply the epitaxial substrate with a 2D material interposer made by claim 6 for a subsequent epitaxial device growth toward a manufacture of AlGaN-based wide bandgap components or the GaN-based laser diode components.
